(19) United States
(12) Patent Application Publication
(10) Pub. No.: US 2026/0096318 A1
(43) Pub. Date: Apr. 2, 2026

(54) DISPLAY PANEL AND DISPLAY DEVICE

(71) Applicant: HKC CORPORATION LIMITED, SHENZHEN (CN)

(72) Inventors: Wenyu YI, SHENZHEN (CN); Zhonglin CAO, SHENZHEN (CN); Chuan WU, SHENZHEN (CN); Dongmei WEI, SHENZHEN (CN); Jie CHEN, SHENZHEN (CN); Fengzhen DANG, SHENZHEN (CN); Yao LI, SHENZHEN (CN); Xiaoxiao YUAN, SHENZHEN (CN); Jiansheng MA, SHENZHEN (CN); Haijiang YUAN, SHENZHEN (CN)

(73) Assignee: HKC CORPORATION LIMITED, SHENZHEN (CN)

(21) Appl. No.: 19/313,486

(22) Filed: Aug. 28, 2025

(30) Foreign Application Priority Data
Sep. 30, 2024 (CN) 202411389817.2

(51) Int. Cl. H10K 59/131; H10K 59/35

(52) U.S. Cl. CPC H10K 59/131; H10K 59/352; H10K 59/353

(57) ABSTRACT

Disclosed are a display panel and a display device. The display panel includes a silicon-based driving substrate and a light-emitting carrier plate; the light-emitting carrier plate includes a glass substrate and a plurality of sub-pixels; the glass substrate has a plurality of anode vias. Each of the sub-pixels is arranged on a surface of a side of the glass substrate. Each of the sub-pixels includes an anode. A diagonal line of each of the sub-pixels is defined as a target diagonal line. Each of the sub-pixels is arranged corresponding to two anode vias, and the two anode vias are located on an extension line of the target diagonal line of one of the sub-pixels. Each of the anode vias is partially overlapped with the corresponding one of the sub-pixels, or ach of the anode vias is misaligned with the corresponding one of the sub-pixels.

### CROSS REFERENCE TO RELATED APPLICATIONS

The present disclosure claims priority to Chinese Patent Application No. 202411389817.2, files on Sep. 30, 2024, the contents of which are herein incorporated by reference in their entirety.

### TECHNICAL FIELD

The present disclosure relates to but not limited to a field of display technologies, and in particular to a display panel and a display device.

### BACKGROUND

An organic light-emitting diode (OLED) display device is a device that uses the reversible color-changeable phenomenon of organic semiconductor materials driven by currents to display graphics. The OLED display device has advantages such as ultra-lightness, ultra-thinness, high brightness, wide viewing angle, low voltage, low power consumption, fast response, high definition, shock resistance, bendability, low cost, simple process, less use of raw materials, high luminous efficiency, and wide temperature range, etc. Therefore, the OLED display technology is considered the most promising new-generation display technology.

However, in the manufacturing process of existing OLED display panels, vias need to be arranged in a planarization layer, while the vias are likely to cause uneven anode deposition, affecting the light-emitting effect of the display panel.

### SUMMARY

A first technical solution provided by the present disclosure is a display panel, and the display panel includes a silicon-based driving substrate and a light-emitting carrier plate bonded to the silicon-based driving substrate; the light-emitting carrier plate includes a glass substrate and a plurality of sub-pixels; the glass substrate has a plurality of anode vias. Each of the sub-pixels is arranged on a surface of a side of the glass substrate. Each of the sub-pixels includes an anode, and the anode of each of the sub-pixels is electrically connected to the silicon-based driving substrate through the anode vias. A diagonal line of each of the sub-pixels is defined as a target diagonal line. Each of the sub-pixels is arranged corresponding to two anode vias, and in a direction parallel to the glass substrate, the two anode vias are located on an extension line of the target diagonal line of a corresponding one of the sub-pixels. In the direction parallel to the glass substrate, each of the anode vias is partially overlapped with the corresponding one of the sub-pixels, or, each of the anode vias is misaligned with the corresponding one of the sub-pixels. A second technical solution provided by the present disclosure is a display device, the display device includes a mainboard and a display panel including a silicon-based driving substrate and a light-emitting carrier plate bonded to the silicon-based driving substrate. The light-emitting carrier plate includes a glass substrate and a plurality of sub-pixels; the glass substrate has a plurality of anode vias. Each of the sub-pixels is arranged on a surface of a side of the glass substrate. Each of the sub-pixels includes an anode, and the anode of each of the sub-pixels is electrically connected to the silicon-based driving substrate through the anode vias. A diagonal line of each of the sub-pixels is defined as a target diagonal line. Each of the sub-pixels is arranged corresponding to two anode vias, and in a direction parallel to the glass substrate, the two anode vias are located on an extension line of the target diagonal line of a corresponding one of the sub-pixels. In the direction parallel to the glass substrate, each of the anode vias is partially overlapped with the corresponding one of the sub-pixels, or, each of the anode vias is misaligned with the corresponding one of the sub-pixels.

### BRIEF DESCRIPTION OF THE DRAWINGS

In order to more clearly illustrate the technical solutions in the embodiments of the present disclosure, the following briefly describes the accompanying drawings used in the embodiments. It is apparent that the drawings in the following description are only some embodiments of the present disclosure. For persons of ordinary skill in the art, other drawings may be derived from these drawings without creative effort.

FIG. 1 is a structural schematic view of a sub-pixel and an anode via provided by the related art.

FIG. 2 is a structural schematic view of a display panel provided by a first embodiment of the present disclosure.

FIG. 3 is a structural schematic view of a repeating virtual quadrilateral in a display panel provided by an embodiment of the present disclosure.

FIG. 4 is a schematic cross-sectional structure view of a display panel provided by an embodiment of the present disclosure.

FIG. 5 is a structural schematic view of a display panel provided by a second embodiment of the present disclosure.

FIG. 6 is a structural schematic view of a display panel provided by a third embodiment of the present disclosure.

FIG. 7 is a structural schematic view of a display panel provided by a fourth embodiment of the present disclosure.

FIG. 8 is a structural schematic view of a display panel provided by a fifth embodiment of the present disclosure.

FIG. 9 is a structural schematic view of a display panel provided by a sixth embodiment of the present disclosure.

FIG. 10 is a schematic cross-sectional structure view of a display panel provided by another embodiment of the present disclosure.

FIG. 11 is a structural schematic view of a display device provided by an embodiment of the present disclosure.

### DETAILED DESCRIPTION

The technical solutions in the embodiments of the present disclosure will be described in detail below with reference to the accompanying drawings.

In the following description, specific details such as system architectures, interfaces, and techniques are provided for illustrative purposes only, not to limit the scope of the disclosure.

In order to make the purpose, technical solutions and advantages of the present disclosure clearer, the following will be described in further detail in conjunction with drawings. Obviously, the described embodiments are only a part of embodiments of the present disclosure, not all embodiments. Based on the embodiments in the present disclosure, all other embodiments obtained by those skilled in the art without creative labor are within the scope of protection of the present disclosure.

In the following description, terms “first/second/third” are used only to distinguish similar objects and do not represent a specific order for the objects, and it is understood that the terms “first/second/third” may be interchanged in a specific order or sequence so that the embodiments of the present disclosure described can be implemented in an order other than the order or sequence described in the drawings and specification. The terms “first”, “second” and “third” in this disclosure are used for descriptive purposes only and are not to be construed as indicating or implying relative importance or as implicitly indicating the quantity of the technical features indicated. Thus, a feature defined as “first”, “second”, or “third” may explicitly or implicitly include at least one of the features. In the description of this disclosure, “multiple” means at least two, such as two, three, etc., unless otherwise expressly specified. All directional indications in the embodiments of this disclosure (e.g. up, down, left, right, front, back . . . ) are only used to explain the relative position relationship and motion between the components in a specific attitude (as shown in the drawings). When the specific attitude changes, the directional indication may also change accordingly. Furthermore, the terms “including” and “having”, and any variation thereof, are intended to cover non-exclusive inclusion. For example, a process, method, system, product or device including a series of steps or units is not limited to the listed steps or units, but optionally also includes steps or units not listed, or optionally includes other steps or units inherent to those processes, methods, products or devices.

A term “embodiment” in the following description describes a subset of all possible embodiments, but it is understood that “embodiment” may be the same subset or a different subset of all possible embodiments, and may be combined with each other without conflict.

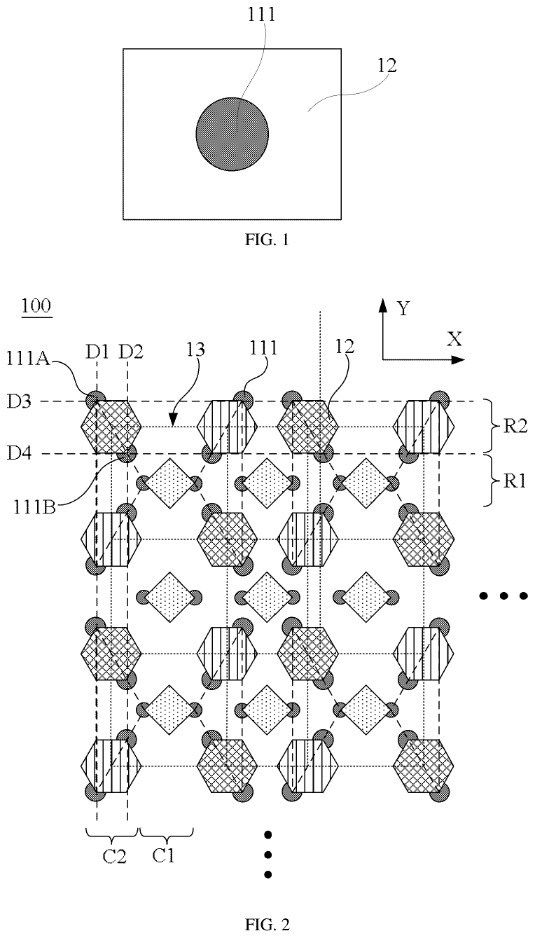

Please refer to FIG. 1, FIG. 1 is a structural schematic view of a sub-pixel and an anode via provided by the related art.

In the related art, each of the anode vias 111 is generally disposed directly below a corresponding one of the sub-pixels 12, and each of the sub-pixels 12 is arranged corresponding to a corresponding one of the anode vias 111. When the punching process is poor, the punching method in the related art may result in a situation where an anode (not shown in FIG. 1) of each one of the sub-pixels 12 and the corresponding one of the anode vias 111 has poor electrical connection, causing the sub-pixel 12 not to light up. Secondly, each of the anode vias 111 is located directly below the corresponding one of the sub-pixels 12 and is arranged facing a light-emitting layer (not shown in FIG. 1) of the corresponding one of the sub-pixels 12, which makes the light-emitting layer of each of the sub-pixels 12 uneven and the light-emitting uniformity different. That is, the brightness of the light-emitting layer in a punched region is different to that in a non-punched region.

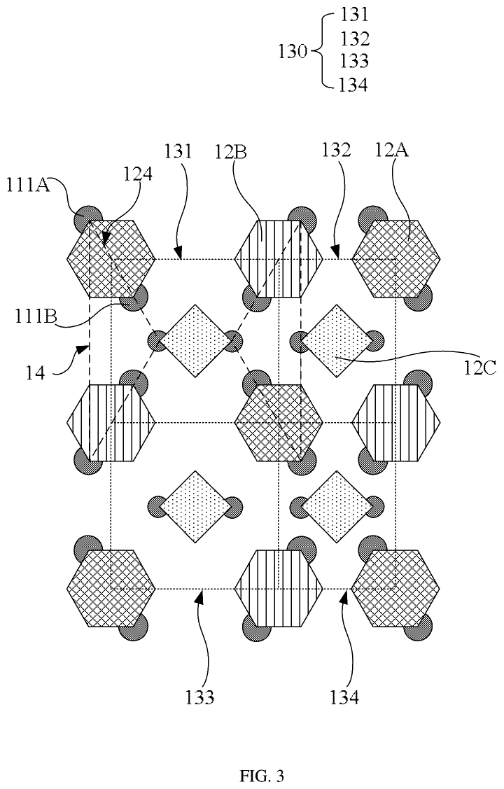

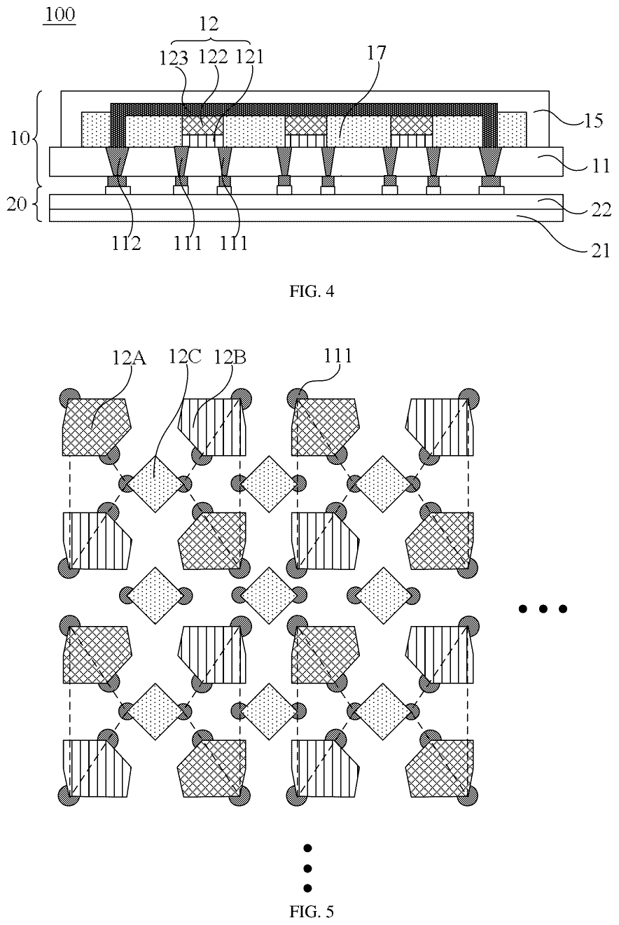

Please refer to FIG. 2 to FIG. 4. FIG. 2 is a structural schematic view of a display panel provided by a first embodiment of the present disclosure. FIG. 3 is a structural schematic view of a repeating virtual quadrilateral in a display panel provided by an embodiment of the present disclosure. FIG. 4 is a schematic cross-sectional structure view of a display panel provided by an embodiment of the present disclosure.

To solve the above technical problem, the present disclosure provides a display panel 100. The display panel 100 includes a silicon-based driving substrate 20 and a light-emitting carrier substrate 10. The light-emitting carrier substrate 10 is bonded to the silicon-based driving substrate 20. The light-emitting carrier substrate 10 includes a glass substrate 11 and a plurality of sub-pixels 12. The glass substrate 11 has a plurality of anode vias 111. Each of the sub-pixels 12 is arranged on a surface of a side of the glass substrate 11. Each of the sub-pixels 12 includes an anode 121, and the anode 121 of each of the sub-pixels 12 is electrically connected to the silicon-based driving substrate 20 through the corresponding anode vias 111. A diagonal line of each of the sub-pixels 12 is defined as a target diagonal line 124. Each one of the sub-pixels 12 is arranged corresponding to two anode vias 111, and in a direction parallel to the glass substrate 11, the two anode vias 111 are located on the extension line of the target diagonal line 124 of a corresponding one of the sub-pixels 12. In the direction parallel to the glass substrate 11, each of the anode vias 111 is partially overlapped with the corresponding one of the sub-pixels 12, or, each of the anode vias 111 is misaligned with the corresponding one of the sub-pixels 12.

By increasing the number of the anode vias 111, stability and reliability of electrical connections are improved, and display anomalies caused by a failure of a single anode via 111 are reduced. Additionally, the arrangement of two anode vias 111 can distribute the current, reduce the resistance, and thus lower the power consumption. Secondly, by separately fabricating and then bonding the light-emitting carrier plate 10 with the sub-pixels 12 and the silicon-based driving substrate 20, the sub-pixels 12 do not need to be directly fabricated on the silicon-based driving substrate 20, which reduces the impact on the driving circuits of the silicon-based driving substrate 20 during the evaporation process of the sub-pixels 12, and consequently reduces losses caused by subsequent process error, and the manufacturing cost of the silicon-based driving substrate 20 is reduced.

The silicon-based driving substrate 20 may include a silicon substrate 21 and a driving circuit layer 22. The driving circuit layer 22 may be disposed on a side of the silicon substrate 21 close to the light-emitting carrier plate 10.

The silicon substrate 21 refers to a substrate based on single-crystalline silicon material.

The drive circuit layer 22 may include an active drive circuit (not shown in the drawing) integrated on the silicon substrate 21 by using the complementary metal-oxide-semiconductor (CMOS) process.

By separately fabricating the silicon-based driving substrate 20 and the light-emitting carrier plate 10, production efficiency is improved. Secondly, the effect of the evaporation process on the silicon-based driving substrate 20 is avoided and the loss of the silicon-based driving substrate 20 is reduced. That is to say, from the perspective of process, separately fabricating the silicon-based driving substrate 20 and the light-emitting carrier plate 10 can not only improve the yield rate but also reduce costs.

The glass substrate 11 may further have cathode vias 112, the cathode vias 112 and the anode vias 111 may be arranged at intervals. A cathode 123 of each of the sub-pixels 12 is electrically connected to the silicon-based driving substrate 20 through a corresponding one of the cathode vias 112.

Both the cathode vias 112 and the anode vias 111 are fabricated by the through-glass via (TGV) technology.

It should be understood that, compared with the through-silicon via (TSV) technology, the TGV technology has advantages of excellent high-frequency electrical characteristics, low cost, simple process and strong mechanical stability.

Compared with the related art in which the sub-pixels 12 are fabricated on the silicon-based driving substrate 20 and electrically connected to the silicon-based driving substrate 20 through through-silicon vias, the sub-pixels 12 in the present disclosure are disposed on the glass substrate 11, by bonding the sub-pixels 12 to the silicon-based driving substrate 20 through through-glass vias, costs may be reduced and the high-frequency electrical characteristics may be improved.

In some embodiments, a ratio range of a size of a single one of the anode vias 111 to a size of the corresponding one of the sub-pixels 12 may be ⅛ to ¼. Without affecting an aperture ratio of each of the sub-pixels 12, the yield of the anode vias 111 and the electrical conductivity between the anode 121 of each of the sub-pixels 12 and the corresponding one of the anode vias 111 are ensured.

The sub-pixels 12 are OLEDs. Each of the sub-pixels 12 may include an anode 121, a light-emitting layer, and a cathode sequentially stacked.

In some embodiments of the present disclosure, the display panel 100 may include sub-pixels 12 of various colors. The color of the sub-pixels 12 is not limited here, and can be selected according to actual needs.

In some embodiments, the size of each of the sub-pixels 12 ranges from 6 microns to 15 microns. It should be understood that the size of each of the sub-pixels 12 may also be other values.

In the direction parallel to the glass substrate 11, a shape of each of the sub-pixels 12 may be a polygon or a combined polygon. The combined polygon of each of the sub-pixels 12 may include a straight side and a curved side (see FIG. 8). The shape of each of the sub-pixels 12 is not limited here, as long as each of the sub-pixels 12 has a diagonal.

The target diagonal line 124 is one of the diagonal lines in each of the sub-pixels 12. That is to say, a single one of the sub-pixels 12 may have only one target diagonal line 124.

Each one of the sub-pixels 12 is arranged corresponding to the two corresponding anode vias 111. The two corresponding anode vias 111 may be respectively located at both ends of the diagonal. The sizes of the two anode vias 111 corresponding to each one of the sub-pixels 12 may be the same or different. The sizes of the anode vias 111 corresponding to each one of the sub-pixels 12 of different colors may also be the same or different.

In the embodiments of the present disclosure, the description is mainly given by taking the example that the sizes of the two anode vias 111 corresponding to each one of the sub-pixels 12 are the same.

The shape of each of the anode vias 111 is not limited here, and it can be selected according to actual needs. In the direction parallel to the glass substrate 11, a cross-section of each of the anode vias 111 may be in the shape of a rectangle, a circle, or a triangle, etc.

In the embodiments of the present disclosure, the description is mainly given by taking the example that the cross-section of each of the anode vias 111 is circular in the direction parallel to the glass substrate 11, so as to facilitate the fabrication of the anode vias 111.

In the direction parallel to the glass substrate 11, each of the anode vias 111 may be arranged to be partially overlapped with the corresponding one of the sub-pixels 12, or each of the anode via 111 may be arranged to be misaligned with the corresponding one of the sub-pixels 12. In the related art, the ratio range of the size of each of the anode vias 111 to the size of corresponding one of the sub-pixels 12 may be from ¼ to ½. That is to say, when the size of each of the sub-pixels 12 is the same, compared with the anode vias 111 in the related art, the size of each of the anode vias 111 in the embodiment of the present disclosure is smaller. By arranging two of the anode vias 111 corresponding to one of the sub-pixels 12, not only can the stability and reliability of the electrical connection be improved, but also the display abnormality caused by the failure of a single one of the anode vias 111 may be reduced. That is, when one of the two corresponding anode vias 111 of each of the sub-pixels 12 fails, the electrical connection can still be realized through the other anode via 111.

It can be understood that, in the direction parallel to the glass substrate 11, when each of the anode vias 111 and the corresponding one of the sub-pixels 12 are partially overlapped, each of the anode vias 111 is located at a diagonal position of the corresponding one of the sub-pixels 12, that is, each of the anode vias 111 is located at an edge of the corresponding one of the sub-pixels 12. Compared with the related art, in the embodiment of the present disclosure, the size of a single one of the anode vias 111 is smaller, and each of the anode vias 111 is located at the diagonal position of the corresponding one of the sub-pixels 12, so that an overlapping area between each of the anode vias 111 and the corresponding one of the sub-pixels 12 is smaller, and each of the anode vias 111 is located at the edge of the corresponding one of the sub-pixels 12, which is more conducive to reducing the effect of the anode vias 111 on the film layer uniformity of the light-emitting layer 122 of the sub-pixels 12.

When each of the anode vias 111 is arranged to be misaligned with the corresponding one of the sub-pixels 12 in the direction parallel to the glass substrate 11, the projection of each of the sub-pixels 12 on the glass substrate 11 may not overlap with the projection of the corresponding anode vias 111 on the glass substrate 11. That is, the anode vias 111 does not affect the film layer uniformity of the light-emitting layer 122 of each of the sub-pixels 12, which is beneficial to improving the light-emitting effect of the sub-pixels 12. Secondly, compared with the related art, the size of a single one of the anode vias 111 in the embodiment of the present disclosure is smaller. Each of the anode vias 111 in the embodiment of present disclosure is arranged misaligned with the corresponding sub-pixel 12, and does not occupy too much space between the sub-pixels 12, that is, it does not affect an aperture ratio of each of the sub-pixels 12. In other words, in the embodiment of the present disclosure, when each of the anode vias 111 is arranged misaligned with the corresponding one of the sub-pixels 12 in the direction parallel to the glass substrate 11, the light-emitting effect of the sub-pixels 12 is improved while the aperture ratio of each of the sub-pixels 12 is not affected.

It should be noted that, in the direction parallel to the glass substrate 11, for the two of the anode vias 111 corresponding to each of the sub-pixels 12, both of the two anode vias 111 may be misaligned with the corresponding one of the sub-pixels 12; alternatively, both of the two anode vias 111 may partially overlap with the corresponding one of the sub-pixels 12; alternatively, one of the two anode vias 111 may be misaligned with the corresponding one of the sub-pixels 12, and the other may partially overlap with the corresponding one of the sub-pixels 12.

In this embodiment, in the direction parallel to the glass substrate 11, each of the anode vias 111 is partially overlapped with the corresponding one of the sub-pixels 12.

In some embodiments, the sub-pixels 12 with different colors are respectively defined as first-color pixels 12A, second-color pixels 12B, and third-color pixels 12C.

The first-color pixels 12A and the second-color pixels 12B may be arranged alternately along a first direction X to form double-color pixel rows R2. The third-color pixels 12C may be arranged at intervals along the first direction X to form monochromatic pixel rows R1. The double-color pixel rows R2 and the monochromatic pixel rows R1 may be arranged alternately along a second direction Y. The first direction X intersects the second direction Y.

The first-color pixels 12A and the second-color pixels 12B may be arranged alternately along the second direction Y to form double-color pixel columns C2. The third-color pixels 12C may be arranged at intervals along the second direction Y to form monochromatic pixel columns C1. The double-color pixel columns C2 and the monochromatic pixel columns C1 are arranged alternately along the first direction X.

The centers of two first-color pixels 12A and two second-color pixels 12B located in two adjacent double-color pixel rows R2 and two adjacent double-color pixel columns C2 form first virtual quadrilaterals 131. Each of the third-color pixels 12C may be located at the center of a corresponding one of the virtual quadrilaterals 13. Two adjacent virtual quadrilaterals 13 may share an adjacent side.

The size of each of the virtual quadrilaterals 13 may be the same or different, it is not limited here and can be selected according to actual needs.

That is to say, each of the virtual quadrilaterals 13 may include two first-color pixels 12A, two second-color pixels 12B and one third-color pixel 12C.

It should be noted that, each of the sub-pixels 12 of the same color in each virtual quadrilateral 13 may have the same shape or different shapes, each of the sub-pixels 12 of different colors in each virtual quadrilateral 13 may have the same shape or different shapes.

In some embodiments, in each of the virtual quadrilaterals 13, the sub-pixels 12 of the same color may be arranged in central symmetry. The two anode vias 111 corresponding to each of the sub-pixels 12 may be respectively defined as a first anode via 111A and a second anode via 111B.

The first anode vias 111A corresponding to all of the sub-pixels 12 in each double-color pixel column C2 may be located on a first straight line D1, and the second anode vias 111B corresponding to all of the sub-pixels 12 in each double-color pixel column may be located on a second straight line D2. Both the first straight line D1 and the second straight line D2 may extend along the second direction Y.

The first anode vias 111A corresponding to all of the sub-pixels 12 in each double-color pixel row may be located on a third straight line D3, the second anode vias 111B corresponding to all of the sub-pixels 12 in each double-color pixel row may be located on a fourth straight line D4, and the third straight line D3 and the fourth straight line D4 may extend along the first direction X.

The first anode vias 111A corresponding to all of the sub-pixels 12 in each of the monochromatic pixel rows R1 may be located on the same straight line, and the straight line may be parallel to the first direction X.

The second anode vias 111B corresponding to all of the sub-pixels 12 in each monochromatic pixel column C1 may be located on the same straight line, and the straight line may be parallel to the second direction Y.

In some embodiments, every four of the virtual quadrilaterals 13 arranged in two adjacent rows and two adjacent columns may form a repeating virtual quadrilateral 130. The repeating virtual quadrilaterals 130 may be arranged in a matrix. In each of the repeating virtual quadrilaterals 130, the four virtual quadrilaterals 13 may be respectively defined as the first virtual quadrilateral 131, the second virtual quadrilateral 132, the third virtual quadrilateral 133, and the fourth virtual quadrilateral 134.

Extension lines of the target diagonal lines 124 of two sub-pixels 12 in a column of each of the first virtual quadrilaterals 131 intersect at the first anode vias 111A corresponding to a corresponding one of the third-color pixels 12C; the extension lines of the target diagonal lines of the other two sub-pixels 12 in the other column of each of the first virtual quadrilaterals 131 intersect at the second anode via 111B corresponding to the corresponding one of the third-color pixels 12C.

Each of the second virtual quadrilaterals 132 may be located at the same row as each of the first virtual quadrilaterals 131, and each of the third virtual quadrilaterals 133 may be located at the same column as each of the first virtual quadrilaterals 131. In each of the second virtual quadrilaterals 132, the first straight line D1 may be arranged on a side of a corresponding second straight line D2 close to a corresponding one of the third-color pixels 12C.

The first anode via 111A of the third-color pixels 12C in each of the second virtual quadrilaterals 132 and the fourth virtual quadrilaterals 134 may be located on a corresponding first straight line D1, and the second anode via 111B of the third-color pixels 12C in each of the second virtual quadrilaterals 132 and the fourth virtual quadrilaterals 134 may be located on other corresponding first straight line D1.

In the above embodiments, a virtual triangular region 14 is formed by four anode vias 111 corresponding to a corresponding one of the first-color pixels 12A and a corresponding one of the second-color pixels 12B in the same column and a corresponding one of the anode vias 111 of a corresponding one of the third-color pixels 12C in each first virtual quadrilateral 131, which may improve the stability of the glass substrate 11 in the virtual triangular region 14 of each first virtual quadrilateral 131, and further improve the stability of the entire glass substrate 11.

It should be understood that in each first virtual quadrilateral 131, two virtual triangular regions 14 may be formed at intervals.

In some embodiments, each of the first color pixels 12A may be arranged in a mirror image with an adjacent one of the second color pixels 12B. In the first direction X, the third color pixels 12C may be arranged at equal intervals. In the second direction Y, the third color pixels 12C may be also arranged at equal intervals.

In some embodiments, a ratio of the light-emitting area of each of the first-color pixels 12A, the light-emitting area of each of the second color-pixels 12B, and the light-emitting area of each of the third-color pixels 12C may be 2:2:1. The first-color pixels 12A may be red pixels, the second-color pixels 12B may be blue pixels, and the third-color pixels 12C may be green pixels. This design is beneficial for subsequent color mixing adjustment.

In this embodiment, in the direction parallel to the glass substrate 11, both the first-color pixels 12A and the second-color pixels 12B may be regular hexagons, and the third-color pixels 12C may be rhombuses.

In other embodiments, the ratio of the light-emitting area of each of the first-color pixels 12A, the light-emitting area of each of the second color-pixels 12B, and the light-emitting area of each of the third-color pixels 12C may be other values. The sub-pixels 12 may also be of other shapes.

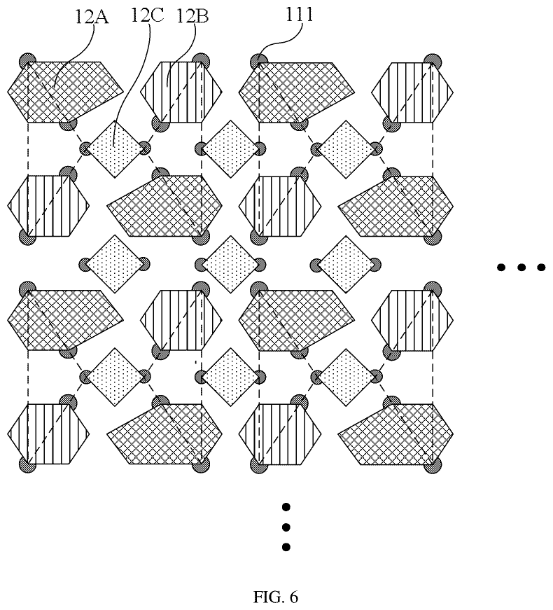

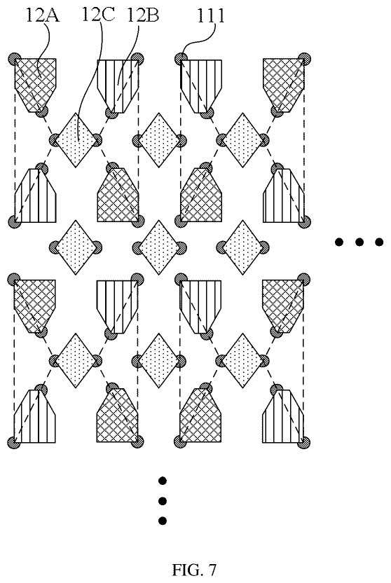

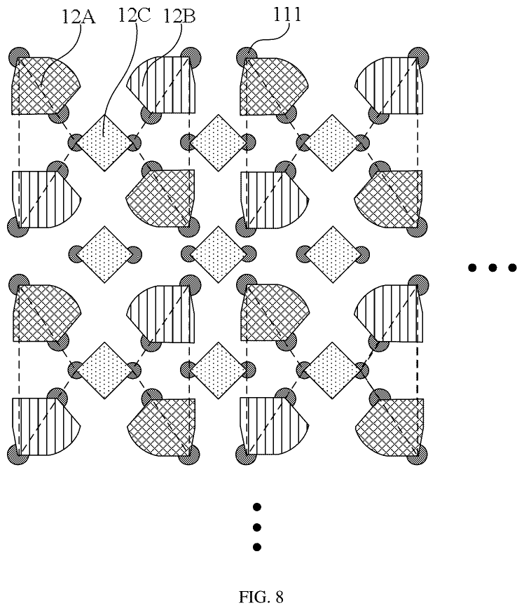

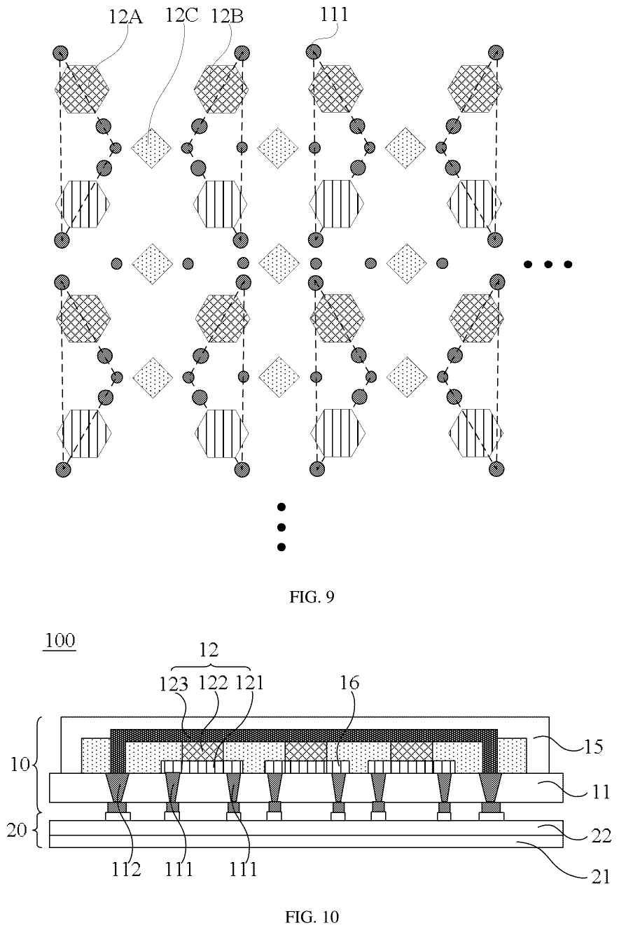

Please refer to FIG. 2 to FIG. 10. FIG. 5 is a structural schematic view of a display panel provided by a second embodiment of the present disclosure. FIG. 6 is a structural schematic view of a display panel provided by a third embodiment of the present disclosure. FIG. 7 is a structural schematic view of a display panel provided by a fourth embodiment of the present disclosure. FIG. 8 is a structural schematic view of a display panel provided by a fifth embodiment of the present disclosure. FIG. 9 is a structural schematic view of a display panel provided by a sixth embodiment of the present disclosure. FIG. 10 is a schematic cross-sectional structure view of a display panel provided by another embodiment of the present disclosure.

In some embodiments, the first-color pixels 12A and the second-color pixels 12B may also be in other shapes. Each of the sub-pixels 12 may be of a symmetric structure (see FIG. 2, FIG. 7 and FIG. 9), or may be of a non-symmetric structure (see FIG. 6 and FIG. 8). In each double-color pixel row R2, the spacing between the sub-pixels 12 may be equal (see FIG. 5 and FIG. 7), or may be unequal (see FIG. 2 and FIG. 8). It should be understood that in each double-color pixel row R2, a uniform spacing between the sub-pixels 12 is beneficial for improving display uniformity.

In some embodiments, as shown in FIG. 6, each of the first-color pixels 12A and a corresponding one of the second-color pixels 12B may also be arranged in a non-mirrored manner, and the shape of each of the first-color pixels 12A may be different with that of each of the second-color pixels 12B.

In some embodiments, as shown in FIG. 9, in the direction parallel to the glass substrate 11, each of the anode vias 111 may be misaligned with the corresponding one of the sub-pixels 12. The display panel 100 may further include anode extension portions 16. Each of the anode extension portions 16 may be arranged in a one-to-one correspondence with a corresponding one of the anode vias 111. The anode extension portions 16 and the anode 121 of each of the sub-pixels 12 may be formed by patterning a same conductive layer. The anode 121 of each of the sub-pixels 12 may be electrically connected to a corresponding one of the anode vias 111 through a corresponding one of the anode extension portions 16. It should be understood that, in the direction parallel to the glass substrate 11, compared with the arrangement that each of the anode vias 111 partially overlaps with the corresponding one of the sub-pixels 12, by arranging each of the anode vias 111 to be misaligned with the corresponding one of the sub-pixels 12, an influence of each of the anode vias 111 on the film uniformity of the light-emitting layer 122 of each of the sub-pixels 12 may be better avoided, and the light-emitting effect of each of the sub-pixels 12 may be better improved.

In some embodiments, the sizes of the anode vias 111 corresponding to the sub-pixels 12 of different colors may be the same or different, and the size may be determined according to actual needs.

The light-emitting carrier plate 10 may further include an encapsulation layer 15, which is located on a side of each of the sub-pixels 12 away from the glass substrate 11. The material of the encapsulation layer 15 is not limited here and may be selected according to actual needs.

The light-emitting carrier plate 10 may further include isolation structures 17. Each of the isolation structures 17 may be arranged on a side of each of the sub-pixels 12 and may be configured to isolate the light-emitting layers 122 of the adjacent sub-pixels 12 to avoid the problem of pixel crosstalk. The isolation structures 17 may isolate the cathode 123 of each of the sub-pixels 12, alternatively, the isolation structures 17 may electrically connect the cathodes 123 of the adjacent sub-pixels 12. The material of the isolation structures 17 is not limited here and may be selected according to actual needs. In this embodiment, the isolation structure 17 also isolates the cathode 123 of each of the sub-pixels 12. The cathode 123 of the sub-pixels 12 may form an integral layer structure. The cathode 123 may be located on a side of each of the isolation structures 17 away from the glass substrate 11.

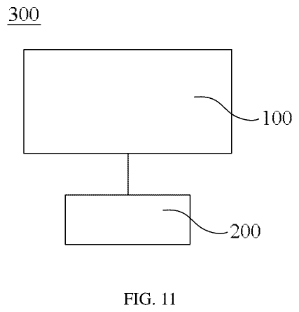

Please refer to FIG. 11, FIG. 11 is a structural schematic view of a display device provided by an embodiment of the present disclosure.

The present disclosure further provides a display device 300. The display device 300 includes a mainboard 200 and the above-mentioned display panel 100. The display device 300 in the embodiment of the present disclosure is an AMOLED.

The mainboard 200 may be electrically connected to the display panel 100. The mainboard 200 may be configured to transmit various required signals to the display panel 100 to control the display panel 100 to display images. For example, the various required signals may include a clock signal (CK), a low potential signal (Vss), a power supply voltage signal (VDD), and a data signal (Data) required by the driving circuit layer, etc.

In the above embodiments, the descriptions of each embodiment have their own emphases. For the parts not elaborated in a certain embodiment, the relevant descriptions of other embodiments may be referred to.

The above are only the embodiments of the present disclosure, which do not limit the protection scope of the present disclosure. Any equivalent structure or equivalent process transformation made using the content of the specification and drawings of the present disclosure, directly or indirectly applied in other related technical fields, is similarly included within the protection scope of the present disclosure.

1. A display panel, comprising:
a silicon-based driving substrate;
a light-emitting carrier plate, bonded to the silicon-based driving substrate and comprising:
a glass substrate, defining a plurality of anode vias; and
a plurality of sub-pixels, each of the sub-pixels is arranged on a surface of a side of the glass substrate and comprises an anode, and the anode of each of the sub-pixels is electrically connected to the silicon-based driving substrate through the anode vias; a diagonal line of each of the sub-pixels is defined as a target diagonal line;
wherein each of the sub-pixels is arranged corresponding to two anode vias, and in a direction parallel to the glass substrate, the two anode vias are located on an extension line of the target diagonal line of a corresponding one of the sub-pixels; and
in the direction parallel to the glass substrate, each of the anode vias is partially overlapped with the corresponding one of the sub-pixels, or, each of the anode vias is misaligned with the corresponding one of the sub-pixels.

2. The display panel according to claim 1, wherein the sub-pixels with different colors are respectively defined as first-color pixels, second-color pixels, and third-color pixels;
the first-color pixels and the second-color pixels are arranged alternately along a first direction to form double-color pixel rows, the third-color pixels are arranged at intervals along the first direction to form monochromatic pixel rows, the double-color pixel rows and the monochromatic pixel rows are arranged alternately along a second direction, and the first direction intersects the second direction;
the first-color pixels and the second-color pixels are arranged alternately along the second direction to form double-color pixel columns; the third-color pixels are arranged at intervals along the second direction to form monochromatic pixel columns; and the double-color pixel columns and the monochromatic pixel columns are arranged alternately along the first direction; and
centers of two first-color pixels and two second-color pixels located on two adjacent double-color pixel rows and two adjacent double-color pixel columns form virtual quadrilaterals, each of the third-color pixels is located on a center of a corresponding one of the virtual quadrilaterals, and two adjacent virtual quadrilaterals share an adjacent side.

3. The display panel according to claim 2, wherein in each of the virtual quadrilaterals, the sub-pixels of the same color are arranged in central symmetry; the two anode vias corresponding to each of the sub-pixels are respectively defined as a first anode via and a second anode via;
the first anode vias corresponding to all of the sub-pixels in each of the double-color pixel columns are located on a first straight line, and the second anode vias corresponding to all of the sub-pixels in each of the double-color pixel columns are located on a second straight line; and both the first straight line and the second straight line extend along the second direction;
the first anode vias corresponding to all of the sub-pixels in each of the double-color pixel rows are located on a third straight line, the second anode vias corresponding to all of the sub-pixels in each of the double-color pixel rows are located on a fourth straight line, and the third straight line and the fourth straight line extend along the first direction;
the first anode vias corresponding to all of the sub-pixels in each of the monochromatic pixel rows are located on a same straight line, and the straight line is parallel to the first direction; and
the second anode vias corresponding to all of the sub-pixels in each of the monochromatic pixel columns are located on a same straight line, and the straight line is parallel to the second direction.

4. The display panel according to claim 3, wherein every four of the virtual quadrilaterals arranged in two adjacent rows and two adjacent columns form a repeating virtual quadrilateral, and repeating virtual quadrilaterals are arranged in a matrix; four virtual quadrilaterals in each of the repeating virtual quadrilaterals are respectively defined as a first virtual quadrilateral, a second virtual quadrilateral, a third virtual quadrilateral, and a fourth virtual quadrilateral;
extension lines of the target diagonal lines of two sub-pixels in a column of each of the first virtual quadrilaterals intersect at the first anode via corresponding to a corresponding one of the third-color pixels; the extension lines of the target diagonal lines of the other two sub-pixels in the other column of each of the first virtual quadrilaterals intersect at the second anode via corresponding to the corresponding one of the third-color pixels;
each of the second virtual quadrilaterals is located on the same row as each of the first virtual quadrilaterals, and each of the third virtual quadrilaterals is located on the same column as each of the first virtual quadrilaterals; in each of the second virtual quadrilaterals, the first straight line is arranged on a side of a corresponding second straight line close to a corresponding one of the third-color pixels; and
the first anode via of the third-color pixels in each of the second virtual quadrilaterals and the fourth virtual quadrilaterals is located on a corresponding first straight line, and the second anode via of the third-color pixels in each of the second virtual quadrilaterals and the fourth virtual quadrilaterals is located on other corresponding first straight line.

5. The display panel according to claim 4, wherein each of the first color pixels is arranged in a mirror image with an adjacent one of the second color pixels;
the third color pixels are arranged at equal intervals in the first direction, and the third color pixels are arranged at equal intervals in the second direction.

6. The display panel according to claim 2, wherein a ratio of the light-emitting area of each of the first-color pixels, the light-emitting area of each of the second color-pixels, and the light-emitting area of each of the third-color pixels is 2:2:1; the first-color pixels are red pixels, the second-color pixels are blue pixels, and the third-color pixels are green pixels.

7. The display panel according to claim 1, wherein a ratio range of a size of a single one of the anode vias to a size of the corresponding one of the sub-pixels is ⅛ to ¼.

8. The display panel according to claim 1, wherein in the direction parallel to the glass substrate, each of the anode vias is misaligned with the corresponding one of the sub-pixels;
the display panel further comprises anode extension portions, each of the anode extension portions is arranged in a one-to-one correspondence with a corresponding one of the anode vias; the anode extension portions and the anode of each of the sub-pixels are formed by patterning a same conductive layer; and the anode of each of the sub-pixels is electrically connected to a corresponding one of the anode vias through a corresponding one of the anode extension portions.

9. The display panel according to claim 1, wherein in the direction parallel to the glass substrate, a shape of each of the sub-pixels is a polygon or a combined polygon; and the combined polygon of each of the sub-pixels comprises a straight side and a curved side.

10. The display panel according to claim 1, wherein the silicon-based driving substrate comprises a silicon substrate and a driving circuit layer, the driving circuit layer is arranged at a side of the silicon substrate close to the light-emitting carrier plate.

11. The display panel according to claim 1, wherein the glass substrate further comprises a plurality of cathode vias, the cathode vias and the anode vias are arranged at intervals.

12. A display device, comprising a mainboard and a display panel,
wherein the display panel comprises:
a silicon-based driving substrate;
a light-emitting carrier plate, bonded to the silicon-based driving substrate and comprising:
a glass substrate, defining a plurality of anode vias; and
a plurality of sub-pixels, each of the sub-pixels is arranged on a surface of a side of the glass substrate and comprises an anode, and the anode of each of the sub-pixels is electrically connected to the silicon-based driving substrate through the anode vias; a diagonal line of each of the sub-pixels is defined as a target diagonal line;
wherein each of the sub-pixels is arranged corresponding to two anode vias, and in a direction parallel to the glass substrate, the two anode vias are located on an extension line of the target diagonal line of a corresponding one of the sub-pixels; and
in the direction parallel to the glass substrate, each of the anode vias is partially overlapped with the corresponding one of the sub-pixels, or, each of the anode vias is misaligned with the corresponding one of the sub-pixels.

13. The display device according to claim 12, wherein the sub-pixels with different colors are respectively defined as first-color pixels, second-color pixels, and third-color pixels;
the first-color pixels and the second-color pixels are arranged alternately along a first direction to form double-color pixel rows, the third-color pixels are arranged at intervals along the first direction to form monochromatic pixel rows, the double-color pixel rows and the monochromatic pixel rows are arranged alternately along a second direction, and the first direction intersects the second direction;
the first-color pixels and the second-color pixels are arranged alternately along the second direction to form double-color pixel columns; the third-color pixels are arranged at intervals along the second direction to form monochromatic pixel columns; and the double-color pixel columns and the monochromatic pixel columns are arranged alternately along the first direction; and
centers of two first-color pixels and two second-color pixels located on two adjacent double-color pixel rows and two adjacent double-color pixel columns form first virtual quadrilaterals, each of the third-color pixels is located on a center of a corresponding one of the virtual quadrilaterals, and two adjacent virtual quadrilaterals share an adjacent side.

14. The display device according to claim 13, wherein in each of the virtual quadrilaterals, the sub-pixels of the same color are arranged in central symmetry; the two anode vias corresponding to each of the sub-pixels are respectively defined as a first anode via and a second anode via;
the first anode vias corresponding to all of the sub-pixels in each of the double-color pixel columns are located on a first straight line, and the second anode vias corresponding to all of the sub-pixels in each of the double-color pixel columns are located on a second straight line; and both the first straight line and the second straight line extend along the second direction;
the first anode vias corresponding to all of the sub-pixels in each of the double-color pixel rows are located on a third straight line, the second anode vias corresponding to all of the sub-pixels in each of the double-color pixel rows are located on a fourth straight line, and the third straight line and the fourth straight line extend along the first direction;
the first anode vias corresponding to all of the sub-pixels in each of the monochromatic pixel rows are located on a same straight line, and the straight line is parallel to the first direction; and
the second anode vias corresponding to all of the sub-pixels in each of the monochromatic pixel columns are located on a same straight line, and the straight line is parallel to the second direction.

15. The display device according to claim 14, wherein every four of the virtual quadrilaterals arranged in two adjacent rows and two adjacent columns form a repeating virtual quadrilateral, and repeating virtual quadrilaterals are arranged in a matrix; four virtual quadrilaterals in each of the repeating virtual quadrilaterals are respectively defined as a first virtual quadrilateral, a second virtual quadrilateral, a third virtual quadrilateral, and a fourth virtual quadrilateral;
extension lines of the target diagonal lines of two sub-pixels in a column of each of the first virtual quadrilaterals intersect at the first anode via corresponding to a corresponding one of the third-color pixels; the extension lines of the target diagonal lines of the other two sub-pixels in the other column of each of the first virtual quadrilaterals intersect at the second anode via corresponding to the corresponding one of the third-color pixels;
each of the second virtual quadrilaterals is located on the same row as each of the first virtual quadrilaterals, and each of the third virtual quadrilaterals is located on the same column as each of the first virtual quadrilaterals; in each of the second virtual quadrilaterals, the first straight line is arranged on a side of a corresponding second straight line close to a corresponding one of the third-color pixels; and
the first anode via of the third-color pixels in each of the second virtual quadrilaterals and the fourth virtual quadrilaterals is located on a corresponding first straight line, and the second anode via of the third-color pixels in each of the second virtual quadrilaterals and the fourth virtual quadrilaterals is located on other corresponding first straight line.

16. The display device according to claim 15, wherein each of the first color pixels is arranged in a mirror image with an adjacent one of the second color pixels;
the third color pixels are arranged at equal intervals in the first direction, and the third color pixels are arranged at equal intervals in the second direction.

17. The display device according to claim 13, wherein a ratio of the light-emitting area of each of the first-color pixels, the light-emitting area of each of the second color-pixels, and the light-emitting area of each of the third-color pixels is 2:2:1; the first-color pixels are red pixels, the second-color pixels are blue pixels, and the third-color pixels are green pixels.

18. The display device according to claim 12, wherein a ratio range of a size of a single one of the anode vias to a size of the corresponding one of the sub-pixels is ⅛ to ¼.

19. The display device according to claim 12, wherein in the direction parallel to the glass substrate, each of the anode vias is misaligned with the corresponding one of the sub-pixels;
the display panel further comprises anode extension portions, each of the anode extension portions is arranged in a one-to-one correspondence with a corresponding one of the anode vias; the anode extension portions and the anode of each of the sub-pixels are formed by patterning a same conductive layer; and the anode of each of the sub-pixels is electrically connected to a corresponding one of the anode vias through a corresponding one of the anode extension portions.

20. The display device according to claim 12, wherein in the direction parallel to the glass substrate, a shape of each of the sub-pixels is a polygon or a combined polygon; and the combined polygon of each of the sub-pixels comprises a straight side and a curved side.
